(19) United States
(12) Patent Application Publication
(10) Pub. No.: US 2019/0184347 A1
(43) Pub. Date: Jun. 20, 2019

(54) APPARATUS, SYSTEM, AND METHOD TO KEEP PARTICLES IN LIQUIDS AND PASTES IN SUSPENSION

(71) Applicant: W. John Seaborn, Longmont, CO (US)

(72) Inventor: W. John Seaborn, Longmont, CO (US)

(21) Appl. No.: 15/844,579

(22) Filed: Dec. 17, 2017

(51) Int. Cl. B01F 3/08; B01F 9/00

(52) U.S. Cl. CPC B01F 3/088; B01F 9/0023; H05K 1/092; B01F 9/0016; B01F 3/0803

(57) ABSTRACT

An apparatus, system, and method to maintain a suspended state of particles in an ink, liquid, or paste. The system includes one or more cartridge caddies to hold cartridges containing the particles in the ink, liquid, or pastes therein, and a drive roller and support roller configuration operable to rotatingly support the one or more cartridge caddies at predetermined speeds. Each caddy includes a shaft and at least two plates disposed on the shaft, each plate including one or more corresponding sockets configured to hold the cartridge therebetween.

### BACKGROUND OF THE INVENTIVE CONCEPT

### 1. Field of the Invention

The present inventive concept relates to an apparatus, system, and method to prevent settling of particles in liquids. More particularly, the present inventive concept relates to an apparatus, system, and method to continuously maintain the integration of ink particles and ink liquid or other particles in a liquid and particle combination product.

### 2. Description of the Related Art

Electrically conductive inks typically use metal particles such as silver to provide the properties needed to perform properly, i.e., electrical conductivity. These particles are typically supported in a liquid suspension medium, and are typically heavy relative to the suspension medium. As a result, the particles tend to settle out of solution over time, especially after the liquids are packaged. The issue of particles settling while packaged is true for many other packaged liquids and pastes made up of particles rendered in a suspended state, including inks and paints.

In order to maintain their usefulness, particle filled inks and similar liquids and pastes must be kept in suspension after being packed for shipment, storage or use in dispensing cartridges. The problem is that the metaphorical clock starts immediately after packaging such liquids and pastes, since the heavy particles will start to sink to the bottom of the suspension. These inks and other liquids and pastes are often expensive, and can be rendered useless if not used within a relatively brief period while the particles are still in suspension. Accordingly, after particle-filled liquids and pastes are packaged, they need to be continually mixed to keep the particles from settling.

Notably, packaged liquid cannot be mixed directly. In a dispensing application of materials such as inks, a degassing process must typically be performed to eliminate air bubbles during packaging thereof. This may be performed by applying a vacuum to the ink or other liquid or paste during packaging to draw out gasses. If the ink is mixed through direct contact with the ink, for example, by inserting a mixer into the ink contained in a cartridge, air is often re-introduced into the liquid. Air bubbles in the ink can cause problems during use thereof, for example, causing skips and gaps during dispensing.

Accordingly, liquids and pastes must be mixed after packaging and without breaching the packaging. Such mixing may include, among other things, rolling and agitating the packaged liquid or paste, using a constant motion of the packaging to keeps particles therein from settling.

However, current methods of mixing such particle filled inks and other liquids and pastes have several limitations. For instance, packaged inks must be kept level during rolling or agitation. If an ink cartridge or other packaged liquid is at an angle while it is rolled, particles will start to settle towards a lower end of the cartridge regardless of rotation. Accordingly, existing methods of keeping particles in suspension can only work with cartridges that can be held level. If a cartridge has an irregular shape, e.g., it is wider at one end, it cannot be mixed effectively. This is typically the case where support “ears” are used to support a cartridge in a rack for storage and/or mixing.

Similarly, currently available mixing devices may only be used with cartridges or other packages of a particular size. Different mixing devices are often required for cartridges of different sizes. This leads to inefficiencies in the mixing process, especially if mixing many different sizes of cartridges is desired.

Furthermore, existing methods of mixing particle filled liquids require inserting packages into a canister or jar to be rolled. As a result, the packages cannot be seen during rolling, which makes tracking of inventory and visual inspection of the materials difficult, if not impossible.

Still further, rolling or agitation of the packages via existing methods often must be started after the packages are inserted into a mixing apparatus, and must be stopped before the packages can be removed. This leads to inefficiency as motors are started up, brought up to speed, and slowed down as part of the processes of mixing and using the inks or other liquids. Additionally, this means that when packages of ink or other liquids are added or removed from a mixing apparatus, the mixing of all packages in the mixing apparatus must be stopped and subsequently re-started, regardless of how many packages are being added or removed.

Accordingly, there is a need for a method, apparatus, and system to more effectively mix inks and other liquids and pastes to keep particles therein in suspension such that the ink and other liquids and pastes can be efficiently used and maintained in high quality form. There is also a need for a method, apparatus, and system to keep particles in ink, other liquids and pastes in suspension through a non-contact means.

### SUMMARY OF THE INVENTIVE CONCEPT

The present general inventive concept provides an apparatus, system, and method to roll particle-filled inks and other liquids and pastes without making direct contact thereto, such that the particles are maintained in suspension.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a mixing system, including a drive roller configured to rotate at a predetermined speed, one or more support rollers spaced apart from and extending in parallel with the drive roller, and one or more caddies disposed between the drive roller and each of the one or more support rollers, each caddy including a shaft, and at least two plates disposed on the shaft, each plate including one or more corresponding sockets, each socket configured to receive a cartridge therein. The rotation of the drive roller may rotate the one or more caddies between the drive roller and each of the one or more support rollers.

In an exemplary embodiment, each of the one or more caddies may be configured to hold one or more cartridges of a predetermined size in the one or more corresponding sockets.

In an exemplary embodiment, the mixing system may further include a first caddy and a second caddy. The one or more corresponding sockets of the first caddy may be configured to hold cartridges of a first size, and the one or more corresponding sockets of the second caddy may be configured to hold cartridges of a second size different from the first size.

In an exemplary embodiment, a rotation speed of the drive roller may be adjustable.

In an exemplary embodiment, the system may include a plurality of caddies. The plurality of caddies may have a uniform diameter of the two or more plates.

In an exemplary embodiment, the one or more corresponding sockets of the one or more caddies may hold the cartridges substantially in parallel with the shaft of each caddy.

In an exemplary embodiment, the corresponding sockets of the one or more caddies may support the cartridges such that an end of each cartridge is disposed within a diameter of the plates.

In an exemplary embodiment, the mixing system may further include a first caddy disposed between the drive roller and a first support roller, and a second caddy disposed between the drive roller and a second support roller.

In an exemplary embodiment, the mixing system may further include first and second caddies disposed along a length of the drive roller, the first and second caddies being disposed between the drive roller and one of the one or more support rollers.

The foregoing and/or other features and utilities of the present general inventive concept may be achieved by providing a cartridge caddy including a shaft, and at least two plates disposed on the shaft and including one or more corresponding sockets configured to receive and support a cartridge therein substantially parallel to the shaft, the at least two plates having the same diameter.

In an exemplary embodiment, the corresponding sockets may be disposed at a location in the plates such that an end of each cartridge remains within the diameter of the plates.

The foregoing and/or other features and utilities of the present general inventive concept may be achieved by providing a method of mixing contents stored in a cartridge, the method including supportingly receiving one or more cartridges storing the contents in a corresponding pair of a respective one or more sockets of a caddy, and rotatingly supporting the caddy on a supporting roller and a drive roller rotating at a predetermined speed.

In an exemplary embodiment, the method may further include controlling a rotation speed of the drive roller according to a predetermined requirement of the contents stored in the cartridges.

In an exemplary embodiment, the method may further include maintaining each cartridge parallel to a shaft of the caddy while the caddy is rotatingly supported. The shaft may be parallel with the supporting roller and the drive roller.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is an isometric illustration of a mixing system according to an exemplary embodiment of the present general inventive concept;

FIG. 2 is an isometric illustration of a mixing system and separate caddy according to an exemplary embodiment of the present general inventive concept; and

FIG. 3 is an isometric illustration of a mixing system according to another exemplary embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. Also, while describing the present general inventive concept, detailed descriptions about related well-known functions or configurations that may diminish the clarity of the points of the present general inventive concept are omitted.

It will be understood that although the terms “first” and “second” are used herein to describe various elements, these elements should not be limited by these terms. These terms are only used to distinguish one element from another element. Thus, a first element could be termed a second element, and similarly, a second element may be termed a first element without departing from the teachings of this disclosure.

Expressions such as “at least one of,” when preceding a list of elements, modify the entire list of elements and do not modify the individual elements of the list.

All terms including descriptive or technical terms which are used herein should be construed as having meanings that are obvious to one of ordinary skill in the art. However, the terms may have different meanings according to an intention of one of ordinary skill in the art, case precedents, or the appearance of new technologies. Also, some terms may be arbitrarily selected by the applicant, and in this case, the meaning of the selected terms will be described in detail in the detailed description of the invention. Thus, the terms used herein have to be defined based on the meaning of the terms together with the description throughout the specification.

Also, when a part “includes” or “comprises” an element, unless there is a particular description contrary thereto, the part can further include other elements, not excluding the other elements. In the following description, terms such as “unit” and “module” indicate a unit to process at least one function or operation, wherein the unit and the block may be embodied as hardware or software or embodied by combining hardware and software.

Hereinafter, one or more exemplary embodiments of the present general inventive concept will be described in detail with reference to accompanying drawings.

Exemplary embodiments of the present general inventive concept are directed to a system and method of mixing inks and other particle filled liquids and pastes by using a mixing system 1000.

For the purposes of the exemplary embodiments described herein, cartridges 210 are described as carrying electrically conductive ink. However, it will be understood that exemplary embodiments of the present general inventive concept may be equally applied to other liquids and pastes comprising particles held in a suspended state.

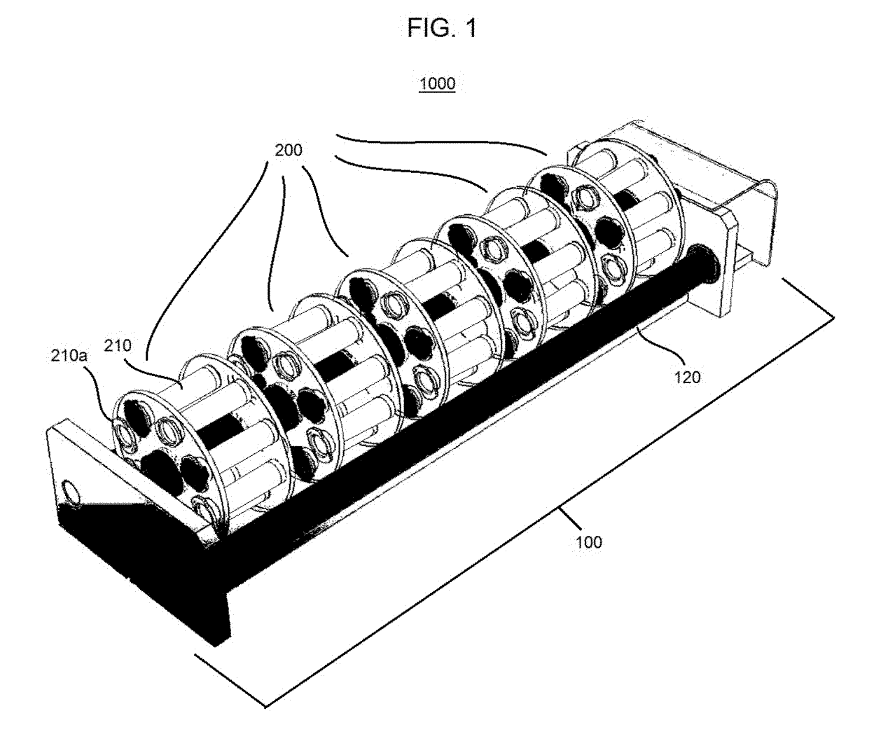

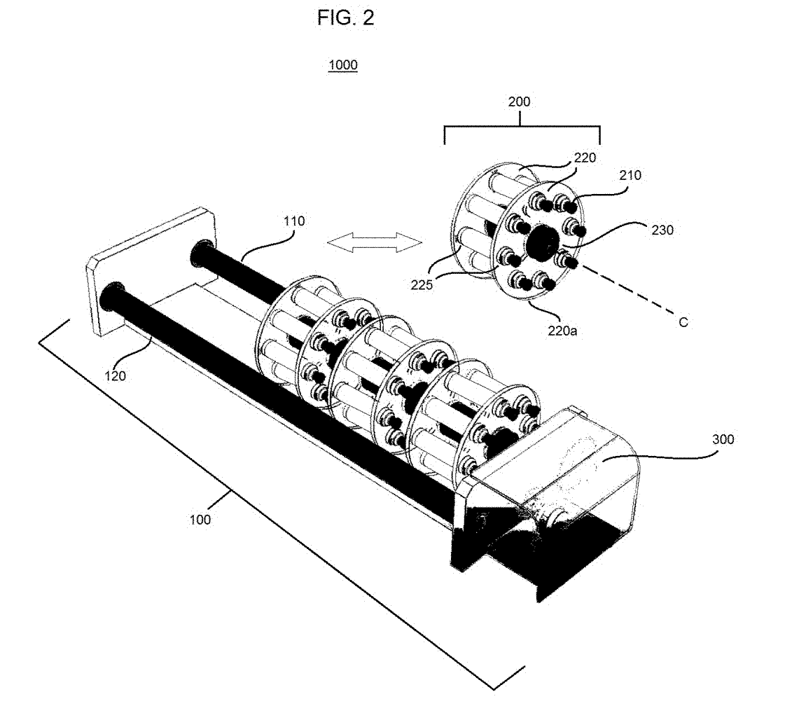

FIGS. 1 and 2 are isometric views of a mixing system 1000 according to an exemplary embodiment of the present general inventive concept. As illustrated therein, exemplary embodiments of the mixing system 1000 may include a base 100 which supports and rotates one or more caddies 200.

The base 100 may include one or more drive rollers 110 and one or more support rollers 120. The drive roller(s) 110 and support roller(s) 120 may support the one or more caddies 200. The drive roller(s) 110 and support roller(s) 120 may be similar in construction. In an exemplary embodiment, each drive roller 110 and each support roller 120 is a cylindrical shaft configured to rotate in the base 100. The support roller(s) 120 may rotate freely, whereas the drive roller(s) 110 are powered, for example by a motor 300 (illustrated in FIG. 2), to rotate at a predefined speed and direction.

Each caddy 200 of the mixing system 1000 may hold one or more cartridges 210. As illustrated in FIG. 2, an exemplary embodiment of a caddy 200 may include a pair of circular plates 220 supported by a shaft 230. Each plate 220 may include one or more sockets 225 to support a cartridge 210. Specifically, a cartridge 210 is supported by being inserted through a corresponding socket 225 aligned in each plate 220.

The caddies 200 may be positioned to hold the cartridges 210 level, i.e., substantially parallel to the shaft 230 and such that gravitational and rotational forces apply to the entire cartridge equally. In an exemplary embodiment, the plates 220 of each caddy 200 have the same diameter, such that cartridges 210 inserted through sockets 225 are held parallel to the shaft 230 regardless of the rotation of the caddy 200. Furthermore, the sockets 225 may be configured to hold cartridges 210 level even when they have an irregular shape. As illustrated in FIG. 1, if a cartridge 210 has “ears” 210a which would make the cartridge 210 wider on one end than the other, the cartridge 210 may still be inserted into a socket 225. In an exemplary embodiment, the ears 210a are not inserted into the socket 225 supporting the corresponding cartridge 210, and furthermore the ears 210a are disposed within a diameter of the plates 220, i.e., the ears do not extend beyond the edge 220a of the plates 220. As such, even if a cartridge 210 has ears 210a, the cartridge 210 may still be held parallel to the shaft 230 without interfering with rolling, such that when the caddy 200 is placed on the drive roller(s) 110 and support roller(s) 120, the cartridge 210 is maintained level.

A continuous frictional contact between the drive roller(s) 110 and an outer edge 220a of the plates 220 of each caddy 200 causes each caddy 200 to continually rotate about its central axis C (an axis running through the shaft 230, as illustrated in FIG. 2). The support roller(s) 120 serve to support the caddy 200 without directly driving the rotation. FIGS. 1-3 illustrate roller configurations according to exemplary embodiments of the present general inventive concept, and are described in greater detail infra.

Each cartridge 210 may contain an ink or other liquid or paste made up of solute particles suspended in a solvent. The particles may settle out of suspension if not continuously mixed. Accordingly, the particles are kept in suspension by first loading one or more cartridges 210 into the sockets 225 of a caddy 200 and placing the caddy 200 onto the drive roller(s) 110 and the support roller(s) 120, which as noted above causes the caddy 200 to rotate about its central axis C. This rotation of the caddy 200 also rotates the cartridges 210 held in the caddy 200, thereby keeping the solute particles in suspension. This mixing occurs without directly contacting the contents of the cartridges 210, thereby avoiding the issue of re-introducing air into the contents of cartridges 210.

It will be understood that the cartridges 210 may be replaced by similar devices requiring non-contact mixing, for example, syringes, barrels, and drums, which cooperate with the intended purposes of the caddy and mixing system 1000 according to the exemplary embodiments present general inventive concept. Furthermore, although the cartridges 210 illustrated in FIGS. 1-3 are tubular in shape, it will be understood that the cartridges 210 and corresponding sockets 225 may have any shape that allows the cartridges 210 to be supported by the plates 220, without affecting the functioning of the system 1000. For example, the cartridges 210 may be rectangular in cross-section, and the sockets 225 may similarly be rectangular in shape to receive and support the cartridges 210.

In an exemplary embodiment each caddy 200 may be open in design. That is, each caddy 200 may support cartridges 210 between plates 220 without enclosing the cartridges 210. This allows the number of cartridges 210, as well as the contents of each cartridge 210, to be visually inspected while each caddy 220 is being rolled on the drive roller(s) 110 and support roller(s) 120.

Since the caddies 200 are not physically attached to the base 100, each caddy 200 may be lifted off the drive roller(s) 110 and support roller(s) 120 and placed thereon quickly and easily, without the need to disengage or unlock any components first. Gravity can hold each caddy 200 securely on the drive roller(s) 110 and support roller(s) 120. In operation, each drive roller 110 is preferably kept turning at a predefined speed regardless of whether a caddy 200 is supported thereon. This allows a caddy 200 to be placed on the drive roller(s) 110 and support roller(s) 120 and removed therefrom quickly and easily, without needing to separately start and stop the rotation of the drive roller(s) 110. Furthermore, this arrangement allows a single caddy 200 to be removed or added to the drive roller(s) 110 and support roller(s) 120 without interrupting the mixing of any caddies 200 already being rolled by the drive roller(s) 110 and support roller(s) 120. FIG. 2 illustrates an exemplary embodiment in which one caddy 200 has been removed from the base 100 while other caddies 200 remain on a drive roller 110 and support roller 120.

The speed of rotation of the drive roller(s) 110 may be set according to a required speed, a particular desired application or a particular liquid or paste being mixed. Due to differing viscosities and different weights of the particles relative to the solvent, some liquids and pastes may require a lower or higher rotation speed than others to keep the solute particles from settling. The speed of rotation of the drive roller 110 may therefore be adjusted, for example by adjusting the speed of a motor 300 turning the drive roller 110.

As pointed out supra, the mixing system 1000 allows caddies 200 to be loaded, removed and replaced on the drive roller(s) 110 and support roller(s) 120 quickly and easily. To recap, the cartridge(s) 210 are the devices that hold the ink or other liquid or paste, the caddy/caddies 200 are the inventive devices that hold the cartridges 210, and the drive roller(s) 110, in conjunction with the support roller(s) 120, are the devices that roll the caddy 200.

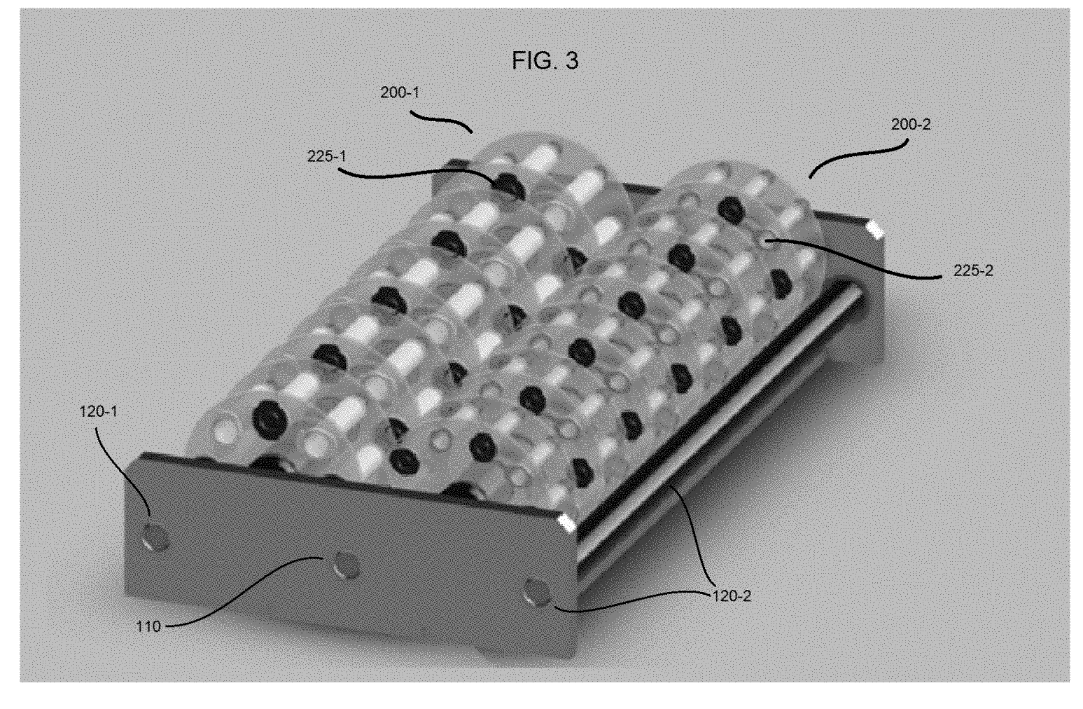

Exemplary embodiments of the mixing system 1000 offer many advantages over existing systems presently used to mix liquids and pastes. Each caddy 200 may be made to hold different cartridges 210 or other packages of ink or other liquid or paste. For example, with reference to FIG. 3, a first caddy 200-1 can have sockets 225-1 to hold 30 cc syringes, while a second caddy 200-2 can have sockets 225-2 to hold 10 cc dispensing cartridges. In an exemplary embodiment, each caddy 200 can be made to hold one specific size of cartridge 210. Dispensing cartridges and other packages of ink or other liquid or paste come in various sizes, capacities, and lengths. Caddies 200 supporting various sizes of dispensing cartridges (e.g., from 3 cc to 100 cc, including increments such as 5 cc, 10 cc, 15 cc, 20 cc, 25 cc, 30 cc, etc.) can be used on the same base 100 at the same time, without need to retool the base 100.

In an exemplary embodiment, each caddy 200 holds cartridges 210 of a particular size and shape. In another exemplary embodiment, individual caddies 200 may hold cartridges 210 having different sizes and shapes. For example, one caddy 200 may include both sockets 225 to hold 10 cc dispensing cartridges and sockets 225 to hold 30 cc syringes.

In an exemplary embodiment, the caddies 200 may be made with a uniform size or diameter of the plates 220, so that different caddies 200 may be turned at the same speed while supported on the drive roller(s) 110 and support roller(s) 120. In such an exemplary embodiment, the base 100, specifically the spacing of the drive roller(s) 110 and support roller(s) 120, may be made according to the particular size of caddy 200, such that the base 100 can securely support caddies 200 of that particular size.

In an alternative embodiment, the same set of drive roller(s) 110 and support roller(s) 120 may be configured to support caddies 200 having different sizes, thereby allowing for more flexibility in the design of each caddy 200. In this exemplary embodiment, the base 100 may simultaneously support and rotate several caddies 200 of different sizes.

Additionally, although each caddy 200 is illustrated to include two plates 220, as illustrated in FIGS. 1-3, it will be understood that a caddy 200 may include any number of plates 220 as may be required to perform the intended purposes of the inventive concept as described herein. In an exemplary embodiment each caddy 200 has at least two plates 220 in order to be supported steadily on the drive roller(s) 110 and support roller(s) 120. Furthermore, in an exemplary embodiment each cartridge 210 is supported by a socket 225 in at least two corresponding plates 220, to hold the cartridge 210 securely and level.

In an exemplary embodiment, cartridges 210 may be added to a caddy 200 and removed therefrom without removing the caddy 200 from the base 100 or stopping the caddy's 200 rotation. Alternatively, if it is desired to remove a caddy 200 from the base 100 (for example, if the rotational speed of the caddy 200 is at a level that makes removing individual cartridges 210 difficult), a desired caddy 200 may be removed by lifting it off the base 100 (see FIG. 2), without the need to stop the drive roller 110. Similarly, a caddy 200 may be added to the system 100 by simply placing the caddy 200 on the base 100, such that the edge 220a of each plate 220 contacts the drive roller 110 and support roller 120, without the need to separately start moving the drive roller 110 after placement thereon. This allows caddies 200 to be quickly and easily moved from the base 100 to a work area (e.g., production area, packaging area, etc.) and from a work area to the base 100. The caddy 200 can hold the cartridges 210 when not on the base 100, for example if the caddy 200 is kept on a work space during production and/or during use of the ink or other liquid or paste in the cartridges 210.

Different configurations of the drive roller(s) 110 and support roller(s) 120 may be used depending on the particular requirement and application as described in the embodiments herein. FIGS. 1 and 3 illustrate different possible configurations of the drive roller(s) 110 and support roller(s) 120. In all cases, it is understood that gravity holds the caddies 200 in place on the drive roller(s) 110 and support roller(s) 120. FIG. 1 illustrates an exemplary embodiment in which a drive roller 110 is disposed to support one side of caddies 200 and a support roller 120 is disposed to support an opposite side of the caddies 200. Several caddies 200 may be positioned longitudinally along the length of the base 100, being rotated by the same drive roller 110 and support roller 120.

FIG. 3 illustrates a mixing system 1000 including multiple pairs of side by side caddies 200-1 and 200-2 according to another exemplary embodiment of the present general inventive concept. As illustrated therein, a single drive roller 110 may be located between each pair of caddies 200-1 and 200-2. Each of the caddies 200-1 and 200-2 can be supported by the drive roller 110 on one side while the support rollers 120-1 and 120-2 can support the other side of the respective caddies 200-1 and 200-2. The rotation of the drive roller 110 may turn all caddies 200 simultaneously. In this configuration, caddies 200 of different sizes may be more easily used. For example, a caddy 200-1 in FIG. 3 may have a different diameter than a caddy 200-2, such that the drive roller 110 turns the different size caddies 200-1 and 200-2 at different speeds. Furthermore, different bases 100 may be configured to more effectively accommodate and support caddies 200 of different sizes. For example, with reference to FIG. 3, if all of the caddies 200-2 have a substantially larger diameter than all of the caddies 200-1, a base 100 may be used in which support roller 120-2 is disposed further away from the drive roller 110 than support roller 120-1.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A mixing system, comprising:
a drive roller configured to rotate at a predetermined speed;
one or more support rollers spaced apart from and extending in parallel with the drive roller; and
one or more caddies disposed between the drive roller and each of the one or more support rollers, each caddy comprising:
a shaft; and
at least two plates disposed on the shaft, each plate including one or more corresponding sockets, each socket configured to receive a cartridge therein,
wherein the rotation of the drive roller rotates the one or more caddies between the drive roller and each of the one or more support rollers.

2. The mixing system of claim 1, wherein each of the one or more caddies is configured to hold one or more cartridges of a predetermined size in the one or more corresponding sockets.

3. The mixing system of claim 2, further comprising:
a first caddy and a second caddy,
wherein:
the one or more corresponding sockets of the first caddy are configured to hold cartridges of a first size; and
the one or more corresponding sockets of the second caddy are configured to hold cartridges of a second size different from the first size.

4. The mixing system of claim 1, wherein a rotation speed of the drive roller is adjustable.

5. The mixing system of claim 1, further comprising:
a plurality of caddies,
wherein the plurality of caddies have a uniform diameter of the two or more plates.

6. The mixing system of claim 1, wherein the one or more corresponding sockets of the one or more caddies hold the cartridges substantially in parallel with the shaft of each caddy.

7. The mixing system of claim 1, wherein the corresponding sockets of the one or more caddies support the cartridges such that an end of each cartridge is disposed within a diameter of the plates.

8. The mixing system of claim 1, further comprising:
a first caddy disposed between the drive roller and a first support roller; and
a second caddy disposed between the drive roller and a second support roller.

9. The mixing system of claim 1, further comprising:
first and second caddies disposed along a length of the drive roller, the first and second caddies being disposed between the drive roller and one of the one or more support rollers.

10. A cartridge caddy, comprising:
a shaft; and
at least two plates disposed on the shaft and including one or more corresponding sockets configured to receive and support a cartridge therein substantially parallel to the shaft, the at least two plates having the same diameter.

11. The cartridge caddy of claim 10, wherein the corresponding sockets are disposed at a location in the plates such that an end of each cartridge remains within the diameter of the plates.

12. A method of mixing contents stored in a cartridge, the method comprising:
supportingly receiving one or more cartridges in a corresponding pair of a respective one or more sockets of a caddy; and
rotatingly supporting the caddy on a supporting roller and a drive roller rotating at a predetermined speed.

13. The method of claim 12, further comprising:
controlling a rotation speed of the drive roller according to a predetermined requirement of the contents stored in the cartridges.

14. The method of claim 12, further comprising:
maintaining each cartridge parallel to a shaft of the caddy while the caddy is rotatingly supported,
wherein the shaft is parallel with the supporting roller and the drive roller.
